(19) United States
(12) Patent Application Publication
(10) Pub. No.: US 2020/0058820 A1
(43) Pub. Date: Feb. 20, 2020

(54) ELECTRICAL CONDUCTIVITY BY MICROWAVE SINTERING

(71) Applicant: Heraeus Precious Metals North America Conshohocken LLC, West Conshohocken, PA (US)

(72) Inventors: Matthias Hoerteis, Bryn Mawr, PA (US); Sylas LaPlante, Philadelphia, PA (US); Gregory Becht, Wilmington, DE (US)

(21) Appl. No.: 16/103,212

(22) Filed: Aug. 14, 2018

(51) Int. Cl. H01L 31/0747; H01L 31/0224; H01L 31/18

(52) U.S. Cl. CPC H01L 31/0747; H01L 31/1884; H01L 31/1804; H01L 31/022483

(57) ABSTRACT

The invention relates to a method for making a HIT solar cell comprising the steps of providing a substrate wherein the substrate comprises amorphous layers on the surfaces of the substrate respectively, providing an electroconductive paste comprising as constituents metallic particles and a polymer system then applying the electroconductive paste to the substrate surface to obtain a precursor and finally heating the precursor through microwave radiation to obtain a solar cell.

### FIELD OF THE INVENTION

The invention relates to a method for preparing temperature sensitive solar cells, particularly HIT (Heterojunction with Intrinsic Thin-layer) solar cells. In particular, the invention relates to a solar cell prepared according to the method of the invention.

### BACKGROUND OF THE DISCLOSURE

Electrodes are an essential part of a wide range of economically important electrical devices, such as solar cells, display screens, electronic circuitry, or parts thereof. One particularly important such electrical device is the solar cell.

Solar cells are devices that convert the energy of light into electricity using the photovoltaic effect. Solar power is an attractive green energy source because it is sustainable and produces only non-polluting by-products. Accordingly, a great deal of research is currently being devoted to developing solar cells with enhanced efficiency while continuously lowering material and manufacturing costs. When light hits a solar cell, a fraction of the incident light is reflected by the surface and the remainder transmitted into the solar cell. The transmitted photons are absorbed by the solar cell, which is usually made of a semiconducting material, such as silicon which is often doped appropriately. The absorbed photon energy excites electrons of the semiconducting material, generating electron-hole pairs. These electron-hole pairs are then separated by p-n junctions and collected by conductive electrodes on the solar cell surfaces.

Solar cells are very commonly based on silicon, often in the form of a Si wafer. Here, a p-n junction is commonly prepared either by providing an n-type doped Si substrate and applying a p-type doped layer to one face or by providing a p-type doped Si substrate and applying an n-type doped layer to one face to give in both cases a so called p-n junction. The face with the applied layer of dopant generally acts as the front face of the cell, the opposite side of the Si with the original dopant acting as the back face. Both n-type and p-type solar cells are possible and have been exploited industrially. Cells designed to harness light incident on both faces are also possible, but their use has been less extensively harnessed.

In order to allow incident light on the front face of the solar cell to enter and be absorbed, the front electrode is commonly arranged in two sets of perpendicular lines known as “fingers” and “bus bars” respectively. The fingers form an electrical contact with the front face and bus bars link these fingers to allow charge to be drawn off effectively to the external circuit.

It is common for this arrangement of fingers and bus bars to be applied in the form of an electro-conductive paste which is fired to give solid electrode bodies. A back electrode is also often applied in the form of an electro-conductive paste which is then fired to give a solid electrode body. The contact forming mechanism between finger and cell may cause slight damage in the emitter which finally increases the electron-hole recombination. In consequence efficiency may be decreasing.

Another approach to solar cell preparation seeks to provide advantageous cell properties by including amorphous silicon layers. Also known as HIT (Heterojunction with Intrinsic Thin Layer) solar cells, such cells can allow reduction of negative effects associated with electron-hole recombination. The amorphous regions in such HIT cells are often temperature sensitive because they are prone to crystallize above a certain temperature.

There is a need in the state of the art for improved methods for the application of electrodes to substrates, particularly if the substrate is temperature sensitive, as is often the case for HIT solar cells.

Processes for preparing HIT solar cells which are known in the prior art use conventional box ovens like for example EP2891158A1.

Conventionally the process for the preparation of a HIT solar cell, the heating is carried out in a box oven or by infrared-heating at a temperature in the range from about 70 to about 250° C., preferably in the range from about 100 to about 230° C. and more preferably in the range from about 130 to about 210° C.

WO2007039227A1 discloses microwave sintering of nanoparticle containing pastes and is focused on flexible polymer substrates. This teaching is completely silent on HIT solar cells comprising amorphous layers.

### SUMMARY OF THE INVENTION

The invention is generally based on the object of overcoming at least one of the problems encountered in the state of the art in relation to electrodes, in particular in relation to electrodes in temperature sensitive solar cells, in particular HIT solar cells.

More specifically, the invention is further based on the object of providing a low temperature process for the preparation of a solar cell which exhibits advantageous cell properties, in particular an advantageously low contact resistance (Rc) of the electrode to the wafer, a low grid resistance (GRFr3) and high mechanical stability. Preferably the continuous electrodes are without disruptions or voids, each affecting the conductivity of the electrodes, commonly called cracking.

A contribution to achieving at least one of the above described objects is made by the subject matter of the category forming claims of the invention. A further contribution is made by the subject matter of the dependent claims of the invention which represent specific embodiments of the invention.

### BRIEF DESCRIPTION OF THE DRAWINGS

The invention is now explained by means of figures which are intended for illustration only and are not to be considered as limiting the scope of the invention. In brief,

FIG. 1 shows a cross sectional view of a common HIT-type layer configuration for a solar cell.

FIG. 2A shows a cross section of an electrode heated in a conventional box oven.

FIG. 2B shows a cross section of an electrode heated in a microwave oven.

FIG. 3A shows a cross section of an electrode heated in a conventional box oven.

FIG. 3B shows a cross section of an electrode heated in a microwave oven.

### DETAILED DESCRIPTION

The following description of the embodiments is merely exemplary in nature and is in no way intended to limit the subject matter of the present disclosure, their application, or uses.

As used throughout, ranges are used as shorthand for describing each and every value that is within the range. Any value within the range can be selected as the terminus of the range. Unless otherwise specified, all percentages and amounts expressed herein and elsewhere in the specification should be understood to refer to percentages by weight.

For the purposes of this specification and appended claims, unless otherwise indicated, all numbers expressing quantities, percentages or proportions, and other numerical values used in the specification and claims, are to be understood as being modified in all instances by the term “about.” The use of the term “about” applies to all numeric values, whether or not explicitly indicated. This term generally refers to a range of numbers that one of ordinary skill in the art would consider as a reasonable amount of deviation to the recited numeric values (i.e., having the equivalent function or result). For example, this term can be construed as including a deviation of ±10 percent, alternatively ±5 percent, alternatively ±1 percent, alternatively ±0.5 percent, and alternatively ±0.1 percent of the given numeric value provided such a deviation does not alter the end function or result of the value. Accordingly, unless indicated to the contrary, the numerical parameters set forth in this specification and attached claims are approximations that can vary depending upon the desired properties sought to be obtained by the present invention.

It is noted that, as used in this specification and the appended claims, the singular forms “a,” “an,” and “the,” include plural references unless expressly and unequivocally limited to one referent. As used herein, the term “include” and its grammatical variants are intended to be non-limiting, such that recitation of items in a list is not to the exclusion of other like items that can be substituted or added to the listed items. For example, as used in this specification and the following claims, the terms “comprise” (as well as forms, derivatives, or variations thereof, such as “comprising” and “comprises”), “include” (as well as forms, derivatives, or variations thereof, such as “including” and “includes”) and “has” (as well as forms, derivatives, or variations thereof, such as “having” and “have”) are inclusive (i.e., open-ended) and do not exclude additional elements or steps. Accordingly, these terms are intended to not only cover the recited element(s) or step(s), but may also include other elements or steps not expressly recited. Furthermore, as used herein, the use of the terms “a” or “an” when used in conjunction with an element may mean “one,” but it is also consistent with the meaning of “one or more,” “at least one,” and “one or more than one.” Therefore, an element preceded by “a” or “an” does not, without more constraints, preclude the existence of additional identical elements.

A contribution to achieving at least one of the above described objects is made by a Method for making a HIT solar cell comprising the steps:
a) Providing a substrate wherein the substrate comprises amorphous layers on the surfaces of the substrate respectively,
b) Providing an electroconductive paste comprising as constituents metallic particles and a polymer system,
c) applying the electroconductive paste to the substrate surface to obtain a precursor and
d) heating the precursor through microwave radiation to obtain a solar cell.

### EMBODIMENTS OF THE INVENTION

In at least one embodiment of the paste, the Ag diameter distribution has at least one maximum in the range from about 1 to about 10 μm, preferably in the range from about 1 to about 5 μm, most preferably in the range from about 1 to about 3 μm.

In at least one embodiment of the paste, the polymer system is a thermoplastic polymer system, wherein the thermoplastic polymer system comprises a thermoplastic polymer.

In at least one embodiment, the thermoplastic polymer shows at least one, preferably two or more and more preferably all of the following parameters:
a. a glass transition temperature in the range from about −120 to about 110° C., preferably in the range from about −50 to about 100° C. and more preferably in the range from about 20 to 80° C.;
b. a melting temperature being at least about 5° C., preferably at least about 30° C. and most preferred about 50° C. higher than the glass transition temperature; or
c. a number average molecular weight in the range from about 10,000 to about 150,000 g/mol, preferably in the range from about 10,000 to about 100,000 g/mol and more preferably in the range from about 11,000 to about 80,000 g/mol.

In one aspect of this embodiment the combination of the parameters a. and b. is preferred.

In at least one embodiment of the paste, the thermoplastic polymer is present in the thermoplastic polymer system in an amount in the range from about 5 to about 45 wt. %, preferably in the range from about 10 to about 40 wt. %, more preferably in the range from about 20 to about 30 wt. %, based on the total weight of the thermoplastic polymer system.

In at least one embodiment of the paste, the thermoplastic polymer is selected from the group consisting of a polyester, an acrylate polymer, a phenoxy polymer, preferable selected from the group consisting of polyester or the acrylate polymer, more preferably polyester.

In at least one embodiment of the paste, the polyester comprises a polyester backbone.

In at least one embodiment of the paste, the polymer system comprises a solvent. Organic solvents are preferred according to one aspect of this embodiment.

In at least one embodiment of the paste, the solvent is an aprotic polar solvent in the thermoplastic polymer system and a protic polar solvent in the thermosetting system.

In at least one embodiment of the paste, the solvent is present in the thermoplastic polymer system in an amount of at least 55 wt. %, preferably at least about 60 wt. %, more preferably at least about 65 wt. %, based on the total weight of the thermoplastic polymer system.

In at least one embodiment of the paste, the solvent is present in the paste in an amount in the range from about 0.1 to 15 wt. %, preferably in the range from about 0.1 to about 12.5 wt. %, more preferably in the range from about 5 to about 10 wt. %, based on the total weight of the paste.

In at least one embodiment of the thermosetting system, no more than 65 wt. %, preferably no more than 60 wt. %, more preferably no more than 55 wt. %, each based on the total weight of the thermosetting polymer, is present in the thermosetting system. In another aspect of this embodiment it is preferred that the solvent is present in the thermosetting system in an amount ranging from about 40 to about 65 wt. % and preferably ranging from about 45 to about 60 wt. %, each based on the total weight of the thermosetting system. In a further aspect of this embodiment it is preferred that no more than about 10 wt. %, preferably no more than about 5 wt. % and more preferred no more than 1 wt. % of the solvent, each based on the total weight of the thermosetting system, is present in the thermosetting system. These thermosetting systems can be considered as “solvent free”.

In at least one embodiment of the paste, no more than 1 wt. %, preferably no more than about 0.5 wt. %, more preferably no more than about 0.3 wt. % of solvent, based on the total weight of the paste, is present in the thermosetting system paste. In another aspect of this embodiment it is preferred that the solvent is present in the thermosetting system paste in an amount ranging from about 1 to about 20 wt. % and preferably ranging from about 5 to about 15 wt. %, each based on the total weight of the thermosetting system paste. In a further aspect of this embodiment it is preferred that no more than about 2 wt. %, preferably no more than about 1 wt. % and more preferred no more than 0.5 wt. % of the solvent, each based on the total weight of the thermosetting system paste, is present in the thermosetting system paste. These pastes can be considered as “solvent free”.

In at least one embodiment of the invention, the paste does not contain more than about 1 wt. %, preferably not more than 0.1 wt. %, more preferably not more than about 0.01 wt. %, glass based on the total weight of the paste. The paste most preferably contains substantially no glass or even more preferred no glass.

In at least one embodiment of the paste, the polymer system is a thermosetting system.

In at least one embodiment of the paste, the thermosetting system comprises a crosslinking compound having at least two unsaturated groups.

In at least one embodiment of the paste, the thermosetting system comprises a radical generator.

In at least one embodiment of the paste, the crosslinking compound is present in the range from about 1 to about 10 wt. %, preferably in the range from about 2 to about 9 wt. %, more preferably in the range from about 3 to about 8 wt. %, based on the total weight of the paste.

In at least one embodiment of the paste, the total weight of Ag particles is in the range from about 60 to about 95 wt. %, preferably in the range from about 70 to about 93 wt. %, more preferably in the range from about 80 to about 90 wt. %, based on the total weight of the paste.

In at least one embodiment of the paste, the crosslinking compound is based on an acrylate, methacrylate or at least one of them.

In at least one embodiment of the paste, the crosslinking compound is based on a fatty acid or a derivative thereof.

In at least one embodiment of the paste, the thermosetting system further comprises a compound having one unsaturated group.

In at least one embodiment of the method according to the invention, the substrate is sensitive to a temperature of not more than 230° C. and preferably not more than 200° C.

In at least one embodiment of the method according to the invention, the substrate is a silicon wafer

In at least one embodiment of the precursor according to the invention, the substrate comprises a p-n junction.

In at least one embodiment of the method according to the invention, the substrate comprises a first silicon layer, wherein less than 50 wt. %, preferably less than 20 wt. %, more preferably less than 10 wt. %, of the first silicon layer is crystalline. In one aspect of this embodiment, the substrate comprises a further silicon layer, wherein at least 50 wt. %, preferably at least 80 wt. %, more preferably at least 90 wt. %, of the further silicon layer is crystalline. In a further aspect of this embodiment, at least the first silicon layer has a dopant level not above about 1×10¹⁶ cm⁻³, preferably not above about 10¹⁴ cm⁻³, more preferably not above about 10¹² cm⁻³. Intrinsic (non-doped) layers preferably contain no intentionally added dopant and more preferably no dopant.

In at least one embodiment of the method according to the invention, the substrate comprises a transparent conductive oxide layer (TCO).

In at least one embodiment of the method according to the invention, the transparent conductive layer is selected from the group consisting of the following: a conductive polymer, a conductive oxide.

A contribution to achieving at least one of the above mentioned objects is made by a method for the preparation of a HIT solar cell at least comprising the following steps:

i) provision of a precursor according to the invention;

ii) heating of the precursor through microwave radiation to obtain the solar cell.

A contribution to achieving at least one of the above mentioned objects is made by a device obtainable by the process according to the invention.

### Substrate

Preferred substrates according to the invention are solid articles to which at least one electrode is applied by a process according to the invention. Substrates are well known to the skilled person and he may choose the substrate as appropriate to suit one of a number of applications. The substrate is preferably chosen in order to improve the electrical and/or physical properties of the electrode-substrate contact as necessary for the particular application.

The substrate may comprise a single material or two or more regions of different materials. Preferred substrates which comprise two or more regions of different materials are layer bodies and/or coated bodies.

Preferred substrate materials are semiconductors; organic materials, preferably polymers; inorganic materials, preferably oxides or glasses; metal layers. The substrate material, or materials, may be insulators, preferably glass, polymers or ceramic; semiconductors, preferably a doped group IV or group III/V element/binary compound, or an organic semiconductor; or conductors, preferably a metallised surface or conductive polymer surface; depending on the intended use of the obtained device. The preferred substrates in the context of this invention are wafers, preferably silicon wafers, preferably for the preparation of a solar cell as described in continuation:

Preferred wafers according to the invention are regions, among other regions of the solar cell, capable of absorbing light with high efficiency to yield electron-hole pairs and separating holes and electrons across a boundary with high efficiency, preferably across a so called p-n junction boundary.

It is preferred for the wafer to consist of appropriately doped tetravalent elements, binary compounds, tertiary compounds or alloys. Preferred tetravalent elements in this context are Si, Ge or Sn, preferably Si. Preferred binary compounds are combinations of two or more tetravalent elements, binary compounds of a group III element with a group V element, binary compounds of a group II element with a group VI element or binary compounds of a group IV element with a group VI element. Preferred combinations of tetravalent elements are combinations of two or more elements selected from Si, Ge, Sn or C, preferably SiC. The preferred binary compounds of a group III element with a group V element is GaAs. It is most preferred according to the invention for the wafer to be based on Si. Si, as the most preferred material for the wafer, is referred to explicitly throughout the rest of this application. Sections of the following text in which Si is explicitly mentioned also apply for the other wafer compositions described above.

It is preferred according to the invention for the substrate to comprise at least one n-type doped layer and at least one p-type doped layer in order to provide a p-n junction boundary.

Doped Si substrates are well known to the person skilled in the art. The doped Si substrate can be prepared in any way known to the person skilled in the art and which he considers to be suitable in the context of the invention. Preferred sources of Si substrates according to the invention are mono-crystalline Si, multi-crystalline Si, amorphous Si and upgraded metallurgical Si, mono-crystalline Si or multi-crystalline Si being most preferred. Doping to form the doped Si substrate can be carried out simultaneously by adding dopant during the preparation of the Si substrate or can be carried out in a subsequent step. Doping subsequent to the preparation of the Si substrate can be carried out for example by gas diffusion epitaxy. Doped Si substrates are also readily commercially available. According to the invention it is one option for the initial doping of the Si substrate to be carried out simultaneously to its formation by adding dopant to the Si mix. According to the invention it is one option for the application of the front doped layer and the highly doped back layer, if present, to be carried out by gas-phase epitaxy. This gas phase epitaxy is preferably carried out at a temperature in a range from about 500° C. to about 900° C., more preferably in a range from about 600° C. to about 800° C. and most preferably in a range from about 650° C. to about 750° C. at a pressure in a range from about 2 kPa to about 100 kPa, preferably in a range from about 10 to about 80 kPa, most preferably in a range from about 30 to about 70 kPa.

In another embodiment of the invention, the substrate, preferably a wafer, comprises one or more amorphous layers. Amorphous layers are preferably layers which are less than 50%, preferably less than 20%, more preferably less than 10% crystalline. Amorphous layers and intrinsic layers (non-doped layers) are preferably employed in order to reduce the frequency of electron-hole re-combinations and thus improve the electrical properties of the cell. It is preferred for the wafer to comprise at least one, preferably at least two, preferably two, nondoped amorphous layers. Non-doped amorphous layers are preferably in contact with a crystalline layer. Preferred non-doped amorphous layers are located on both faces of a crystalline layer. Preferred non-doped amorphous layers have a thickness of 10-20 nm. Non-doped amorphous layers which are in direct contact with a (preferably doped) crystalline silicon layer can also be termed intrinsic layers.

It is preferred for the wafer to comprise at least one, preferably at least two, preferably two, doped amorphous layers, preferably at least one n-type doped amorphous layer and at least one p-type doped amorphous layer.

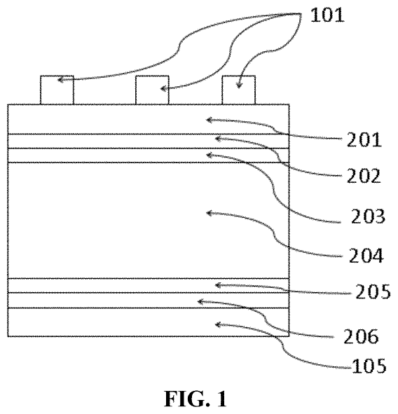

A preferred layer structure of a substrate according to the invention is shown in FIG. 1. The term “substrate” preferably means all the required and optional layers apart from the electrodes.

It is known to the person skilled in the art that Si substrates can exhibit a number of shapes, surface textures and sizes. The shape can be one of a number of different shapes including cuboid, disc, wafer and irregular polyhedron amongst others. The preferred shape according to the invention is wafer shaped where that wafer is a cuboid with two dimensions which are similar, preferably equal and a third dimension which is significantly less than the other two dimensions. Significantly less in this context is preferably at least a factor of about 100 smaller.

The two larger dimensions of the Si substrate can be varied to suit the application required of the resultant solar cell. It is preferred according to the invention for the thickness of the Si wafer to lie below about 0.5 mm more preferably below about 0.3 mm and most preferably below about 0.2 mm. Some wafers have a minimum size of about 0.01 mm or more.

A highly doped layer can be applied to the back face of the Si substrate between the back doped layer and any further layers. Such a highly doped layer is of the same doping type as the back doped layer and such a layer is commonly denoted with a +(n⁺-type layers are applied to n-type back doped layers and p⁺-type layers are applied to p-type back doped layers). This highly doped back layer serves to assist metallisation and improve electro-conductive properties at the substrate/electrode interface area. It is preferred according to the invention for the highly doped back layer, if present, to have a thickness in a range from about 1 to about 100 μm, preferably in a range from about 1 to about 50 μm and most preferably in a range from about 1 to about 15 μm.

### Dopants

Preferred dopants are those which, when added to the Si wafer, form a p-n junction boundary by introducing electrons or holes into the band structure. It is preferred according to the invention that the identity and concentration of these dopants is specifically selected so as to tune the band structure profile of the p-n junction and set the light absorption and conductivity profiles as required. Preferred p-type dopants according to the invention are those which add holes to the Si wafer band structure. They are well known to the person skilled in the art. All dopants known to the person skilled in the art and which he considers to be suitable in the context of the invention can be employed as p-type dopant. Preferred p-type dopants according to the invention are trivalent elements, particularly those of group 13 of the periodic table. Preferred group 13 elements of the periodic table in this context include but are not limited to B, Al, Ga, In, Tl or a combination of at least two thereof, wherein B is particularly preferred.

Preferred n-type dopants according to the invention are those which add electrons to the Si wafer band structure. They are well known to the person skilled in the art. All dopants known to the person skilled in the art and which he considers to be suitable in the context of the invention can be employed as n-type dopant. Preferred n-type dopants according to the invention are elements of group 15 of the periodic table. Preferred group 15 elements of the periodic table in this context include N, P, As, Sb, Bi or a combination of at least two thereof, wherein P is particularly preferred.

As described above, the various doping levels of the p-n junction can be varied so as to tune the desired properties of the resulting solar cell.

According to the invention, it is preferred for the back doped layer to be lightly doped, preferably with a dopant concentration in a range from about 1×10¹³ to about 1×10¹⁸ cm⁻³, preferably in a range from about 1×10¹⁴ to about 1×10¹⁷ cm⁻³, most preferably in a range from about 5×10¹⁵ to about 5×10¹⁶ cm⁻³. Some commercial products have a back doped layer with a dopant concentration of about 1×10¹⁶.

It is preferred according to the invention for the highly doped back layer (if one is present) to be highly doped, preferably with a concentration in a range from about 1×10¹⁷ to about 5×10²¹ cm⁻³, more preferably in a range from about 5×10¹⁷ to about 5×10²⁰ cm⁻³, and most preferably in a range from about 1×10¹⁸ to about 1×10²⁰ cm-3.

It is preferred for intrinsic (non-doped) layers not to have a dopant level above about 1×10¹⁶ cm⁻³, preferably not above about 10¹⁴ cm⁻³, more preferably not above about 10¹² cm⁻³. Intrinsic (non-doped) layers preferably contain no dopant.

### Electro-Conductive Paste

Preferred electro-conductive pastes suitable for the invention are pastes which can be applied to a substrate and which, on heating by using microwave radiation, form solid electrode bodies in physical and/or electrical contact with that substrate. The constituents of the paste and proportions thereof can be selected by the person skilled in the art in order that the paste have the desired properties such as adhesiveness and printability and that the resulting electrode have the desired electrical and physical properties. Metallic particles can be present in the paste, primarily in order that the resulting electrode body be electrically conductive. In order to bring about improved hardening and adhesion, a thermosetting system can be employed. An example composition of an electrically-conductive paste which is preferred in the context of the invention might comprise:
i) Ag particles,
ii) a polymer system
iii) additives, preferably in a range from about 0.01 to about 22 wt. %, more preferably in a range from about 0.05 to about 15 wt. % and most preferably in a range from about 0.1 to about 10 wt. %;
wherein the wt. % are each based on the total weight of the electro-conductive paste and add up to 100 wt. %. In one aspect of this embodiment no more than 1 wt. %, preferably no more than 0.5 wt. % and more preferably no additive is present in the paste.

In at least one embodiment of the invention, the polymer system is a thermosetting system comprising the following constituents:
a. a crosslinking compound, preferably in the range from about 10 to about 99.999 wt. %, more preferably in the range from about 20 to about 99 wt. %, most preferably in the range from about 20 to about 99 wt. %, based on the total weight of the thermosetting system;
b. a radical generator, preferably in the range from about 0.0001 to about 3 wt. %, more preferably in the range from about 0.01 to about 2 wt. %, most preferably in the range from about 0.01 to about 1 wt. %, based on the total weight of the thermosetting system;
c. optionally a solvent, making up the remaining weight of the thermosetting system, 0 wt. % or greater, preferably at least about 20 wt. %, more preferably at least about 30 wt. %, based on the total weight of the thermosetting system;
d. optionally a mono-unsaturated compound, preferably in the range from about 1 to about 10 wt. %, more preferably in the range from about 2 to about 8 wt. %, most preferably in the range from about 4 to about 5 wt. %.

In another embodiment of the invention, the polymer system is a thermoplastic system comprising the following components:
a. a thermoplastic polymer;
b. a solvent.

In order to facilitate printability of the electro-conductive paste, it is preferred according to the invention that the viscosity of the electro-conductive paste lies in a range from about 100 to about 400 Pa. s, preferably 50 to about 300 Pa. s.

It is preferred that the paste is curable at low temperatures, preferably below about 250° C., more preferably below about 230° C., most preferably below about 210° C. Preferably this requirement is valid irrespective of the used heating method.

In at least one embodiment, it is therefore preferred that curing, hardening and adhesion functions be facilitated by a polymer system rather than by an inorganic glass or a glass frit. In at least one embodiment of the invention, the paste does not contain more than about 1 wt. %, preferably not more than about 0.1 wt. %, more preferably not more than about 0.01 wt. % of an inorganic glass or a glass frit. It is preferred for the paste to contain no such glass.

In another embodiment the electro-conductive paste may contain an inorganic glass or a glass frit. A glass frit may improve the mechanical adhesion of the electrode to the surface of the substrate, i.e. a HIT-wafer.

### Metallic Particles

Preferred metallic particles in the context of the invention are those which exhibit metallic conductivity or which yield a substance which exhibits metallic conductivity on heating. Metallic particles present in the electro-conductive paste give metallic conductivity to the solid electrode which is formed when the electro-conductive paste is sintered on heating. Metallic particles which favour effective adhesion and yield electrodes with high conductivity and low contact resistance are preferred. Metallic particles are well known to the person skilled in the art. All metallic particles known to the person skilled in the art and which he considers suitable in the context of the invention can be employed as the metallic particles in the electro-conductive paste. Preferred metallic particles according to the invention are metals, alloys, mixtures of at least two metals, mixtures of at least two alloys or mixtures of at least one metal with at least one alloy.

Preferred metals which can be employed as metallic particles according to the invention are Ag, Cu, Al, Zn, Pd, Ni or Pb and mixtures of at least two thereof, preferably Ag. Preferred alloys which can be employed as metallic particles according to the invention are alloys containing at least one metal selected from the list of Ag, Cu, Al, Zn, Ni, W, Pb and Pd or mixtures or two or more of those alloys.

In at least one embodiment according to the invention, the metallic particles comprise a metal or alloy coated with one or more further different metals or alloys, for example copper coated with silver.

In at least one embodiment according to the invention, the metallic particles are Ag. In another embodiment according to the invention, the metallic particles comprise a mixture of Ag with Al.

As additional constituents of the metallic particles, further to above mentioned constituents, those constituents which contribute to more favourable electrical contact, adhesion and electrical conductivity of the formed electrodes are preferred according to the invention. All additional constituents known to the person skilled in the art and which he considers to be suitable in the context of the invention can be employed in the metallic particles.

It is well known to the person skilled in the art that metallic particles can exhibit a variety of shapes, surfaces, sizes, surface area to volume ratios, oxygen content and oxide layers. A large number of shapes are known to the person skilled in the art. Some examples are spherical, angular, elongated (rod or needle like) and flat (sheet like). Metallic particles may also be present as a combination of particles of different shapes. Metallic particles with a shape, or combination of shapes, which favours advantageous electrical contact, adhesion and electrical conductivity of the produced electrode are preferred according to the invention. One way to characterise such shapes without considering surface nature is through the parameters length, width and thickness. In the context of the invention the length of a particle is given by the length of the longest spatial displacement vector, both endpoints of which are contained within the particle. The width of a particle is given by the length of the longest spatial displacement vector perpendicular to the length vector defined above both endpoints of which are contained within the particle. The thickness of a particle is given by the length of the longest spatial displacement vector perpendicular to both the length vector and the width vector, both defined above, both endpoints of which are contained within the particle.

Preferred uniform shapes in the context of the invention are spheres. In the following, spherical particles will be used to designate particles with ratios relating the length, the width and the thickness which are close to 1, preferably in the range from about 0.3 to about 3, more preferably in the range from about 0.5 to about 2, most preferably in the range from about 0.8 to about 1.8.

In at least one embodiment at least 50 wt. %, preferably at least 80 wt. %, more preferably at least about 90 wt. %, of the Ag particles are spherical.

### Particle Size

It is preferred that the median particle diameter d₅₀ of the metallic particles be at least about 0.1 μm, and preferably at least about 0.5 μm. At the same time, the d₅₀ is preferably no more than about 3 μm, and more preferably no more than about 2 μm.

In at least one embodiment, the metallic particles are spherical: at least 50 wt. %, preferably at least about 80 wt. %, more preferably at least about 90 wt. % of the Ag particles with a diameter in the range from about 0.1 μm to about less than 1 mm are spherical.

A variety of surface types are known to the person skilled in the art. Surface types which favour effective sintering and yield advantageous electrical contact and conductivity of produced electrodes are favoured for the surface type of the metallic particles according to the invention.

Another way to characterise the shape and surface of a metallic particle is by its surface area to weight ratio, also known as specific surface area. The specific surface area can be determined using the BET method. The lowest value for the surface area to weight ratio of a particle is embodied by a sphere with a smooth surface. The less uniform and uneven a shape is, the higher its surface area to weight ratio will be. In at least one embodiment according to the invention, metallic particles with a high specific surface area ratio are preferred, preferably in a range from about 0.1 to about 25 m²/g, more preferably in a range from about 0.5 to about 20 m²/g and most preferably in a range from about 1 to about 15 m²/g. In another embodiment according to the invention, metallic particles with a low specific surface area are preferred, preferably in a range from about 0.01 to about 10 m²/g, more preferably in a range from about 0.05 to about 5 m²/g and most preferably in a range about 0.10 to about 1 m²/g.

It is preferred according to the invention that the diameter distribution of the metallic particles be selected so as to reduce the occurrence of areas of low Ag density in the electrode. The person skilled in the art may select the diameter distribution of the metallic particles to optimise advantageous electrical and physical properties of the resultant solar cell. It is preferred according to the invention for the Ag particles to comprise Ag nano-particles and Ag micro-particles and thus to exhibit a multimodal diameter distribution.

The metallic particles may be present with a surface coating. Any such coating known to the person skilled in the art and which he considers to be suitable in the context of the invention can be employed on the metallic particles. Preferred coatings according to the invention are those coatings which promote improved printing, sintering and etching characteristics of the electro-conductive paste. If such a coating is present, it is preferred according to the invention for that coating to correspond to no more than about 10 wt. %, preferably no more than about 8 wt. %, most preferably no more than about 5 wt. %, in each case based on the total weight of the metallic particles.

In at least one embodiment according to the invention, the metallic particles are present as a proportion of the electro-conductive paste more than about 50 wt. %, preferably more than about 70 wt. %, most preferably more than about 80 wt. %.

### Thermosetting System

In at least one embodiment of the invention, the polymer system is a thermosetting system. Preferred thermosetting systems in the context of the invention ensure that the constituents of the electro-conductive paste are present in the form of solutions, emulsions or dispersions and facilitate irreversible hardening or curing to form an electrode. Preferred thermosetting systems are those which provide optimal stability of constituents within the electro-conductive paste and endow the electro-conductive paste with a viscosity allowing effective line printability. Preferred thermosetting systems yield thermosets showing good adhesion on the wafer of the photovoltaic solar cell, are chemically stable under the conditions under which the photovoltaic solar cell is operated in order to guaranty a long operation time of the photovoltaic solar cell, shall not melt at the operation temperatures of the photovoltaic solar cell and should not particular harm the conductivity of the Ag electrode of the photovoltaic solar cell.

Preferred thermosetting systems according to the invention comprise as components:
a. a crosslinking compound, preferably in the range from about 10 to about 99.999 wt. %, more preferably in the range from about 20 to about 99 wt. %, most preferably in the range from about 20 to about 99 wt. %, based on the total weight of the thermosetting system;
b. a radical generator, preferably in the range from about 0.0001 to about 3 wt. %, more preferably in the range from about 0.01 to about 2 wt. %, most preferably in the range from about 0.01 to about 1 wt. %, based on the total weight of the thermosetting system;
c. optionally a solvent, making up the remaining weight of the thermosetting system, 0 wt. % or greater, preferably at least about 20 wt. %, more preferably at least about 30 wt. %, based on the total weight of the thermosetting system;
d. optionally a mono-unsaturated compound, preferably in the range from about 1 to about 10 wt. %, more preferably in the range from about 2 to about 8 wt. %, most preferably in the range from about 4 to about 5 wt. %;
   wherein the wt. % are each based on the total weight of the thermosetting system and add up to 100 wt. %. According to the invention preferred thermosetting systems are those which allow for the preferred high level of printability of the electro-conductive paste described above to be achieved.

The thermosetting system preferably cures irreversibly on heating. It is therefore preferred that the thermosetting system considered as a whole, and preferably also the individual components, especially a and d, exhibit a thermal hysteresis of hardness. In at least one embodiment the thermosetting system is not a thermoplastic system. In another embodiment, at least one of the constituents a or d, preferably both constituents a and d, is not a thermoplastic.

### Crosslinking Compound

Preferred crosslinking compounds in the context of the invention are compounds which contribute to thermosetting behaviour, preferably facilitating irreversible hardening under curing conditions. It is preferred that the crosslinking compound forms interlinked polymeric networks on hardening/curing. Preferred hardening/curing conditions are one or more of the following: presence of a polymerisation initiator, preferably a radical initiator, heating, or electro-magnetic radiation.

The crosslinking compound preferably comprises at least two unsaturated double bonds, preferably carbon-carbon double bonds.

Preferred crosslinking compounds can be monomers, oligomers, or polymers. In oligomers or polymers, the unsaturated groups may be present in the main chain or in substituents or branches. Preferred unsaturated groups are alkene groups, vinyl ether groups, ester groups, and alkyne groups, preferably alkenes or alkynes, most preferably alkenes. Preferred esters groups are alkyl or hydroxyl acrylates or methacrylates, preferably methyl-, ethyl-, butyl, 2-ethylhexyl- or 2-hydroxyethyl-acrylates, isobornylacrylate-, methylmethacrylate-, or ethylmethacrylate-groups. Other preferred ester groups are siliconacrylates. Other preferred monounsaturated groups are acrylonitrile-, acrylamide-, methacrylamide groups, N-substituted (methy)acrylamide-, vinyl ester-, such as vinyl acetate-, vinyl ether-, styrene-, alkyl- or halo styrene-, n-vinylpyrrolidone-, vinyl chloride-, or vinylidene chloride-groups.

In at least one embodiment of the invention, the crosslinking polymer comprises at least one ester group. In one aspect of this embodiment, at least one unsaturated group is present on the acid side of the ester. In another aspect of this embodiment, at least one unsaturated group is present on the alcohol side of the ester. Preferred unsaturated carboxylic acids in this context are acrylic acid, acrylic acid derivatives, preferably methacrylic acid, or unsaturated fatty acids. Preferred unsaturated fatty acids can be mono-unsaturated or multiply unsaturated, preferably Myri stoleic acid CH₃(CH₂)₃CH═CH(CH₂)₇COOH, Palmitoleic acid CH₃(CH₂)₅CH═CH(CH₂)₇COOH, Sapienic acid CH₃(CH₂)₈CH═CH(CH₂)₄COOH, Oleic acid CH₃(CH₂)₇CH═CH(CH₂)₇COOH, Elaidic acid CH₃(CH₂)₇CH═CH(CH₂)₇COOH, Vaccenic acid CH₃(CH₂)₅CH═CH(CH₂)₉COOH, Linoleic acid CH₃(CH₂)₄CH═CHCH₂CH═CH(CH₂)₇COOH, Linoelaidic acid CH₃(CH₂)₄CH═CHCH₂CH═CH(CH₂)₇COOH, a-Linolenic acid CH₃CH₂CH═CHCH₂CH═CHCH₂CH═CH(CH₂)₇COOH, Arachidonic acid

CH₃(CH₂)₄CH═CHCH₂CH═CHCH₂CH═CHCH₂CH═CH(CH₂)₃COOH, Eicosapentaenoic acid CH₃CH₂CH═CHCH₂CH═CHCH₂CH═CHCH₂CH═CHCH₂CH═CH(CH₂)₃COOH, Erucic acid CH₃(CH₂)₇CH═CH(CH₂)₁₁COOH, or Docosahexaenoic acid CH₃CH₂CH═CHCH₂CH═CHCH₂CH═CHCH₂CH═CHCH₂CH═CHCH₂CH═CH(CH₂)₂COOH, or two or more thereof.

Preferred saturated carboxylic acids in this context are fatty acids, preferably C₉H₁₉COOH (capric acid), C₁₁H₂₃COOH (Lauric acid), C₁₃H₂₇COOH (myristic acid) C₁₅H₃₁COOH (palmitic acid), C₁₇H₃₅COOH (stearic acid) or mixtures thereof. Preferred carboxylic acids with unsaturated alkyl chains are C₁₈H₃₄O₂ (oleic acid) and C₁₈H₃₂O₂ (linoleic acid).

Preferred alcohols in this context may be mono alcohols, diols, or poly-alcohols, preferably sugars. Preferred alcohols are cellulose, glycols, and glycerol.

In at least one embodiment, the crosslinking compound is formed of a polymer chain with substituents, preferably joined to the chain by an ester group. Preferred polymer backbones are poly acrylates, polyurethanes, polystyrenes, polyesters, polyamides and sugars. The preferred substituents are unsaturated fatty acids and acrylates.

### Mono-Unsaturated Compound

Preferred mono-unsaturated compounds in the context of the invention are incorporated into the thermoset network on curing. The mono-unsaturated compound preferably decreases the density of the thermoset network. The skilled person is aware of the use of monounsaturated compounds in a thermosetting system for tuning the properties thereof to the desired application and in order to tune properties such as rate of hardening, conditions required for hardening and density of the thermoset resulting from hardening. Preferred mono-unsaturated compounds are esters, vinyl ethers, amides and vinyl compounds, preferably esters. Preferred esters are alkyl or hydroxyl acrylates or methacrylates, preferably methyl-, ethyl-, butyl-, 2-ethylhexyl- or 2-hydroxyethyl-acrylate, isobornylacrylate, methylmethacrylate, or ethylmethacrylate. Other preferred esters are siliconacrylates. Other preferred mono-unsaturated compounds are acrylonitrile, acrylamide, methacrylamide, N-substituted (methy)acrylamide, vinyl ester, such as vinyl acetate, vinyl ether, such as isobutyl vinyl ether, styrene, alkyl or halo styrenes, n-vinylpyrrolidone, vinyl chloride, or vinylidene chloride.

### Solvent in the Thermosetting System

Preferred solvents in the thermosetting system are constituents of the thermosetting system which are removed to a significant extent during heating, preferably those which are present after heating with an absolute weight reduced by at least about 80% compared to before heating, preferably reduced by at least about 95% compared to before heating. Preferred solvents according to the invention are those which allow an electro-conductive paste to be formed which has favourable viscosity, printability, stability and adhesive characteristics and which yields electrodes with favourable electrical conductivity and electrical contact to the substrate. Solvents are well known to the person skilled in the art.

All solvents which are known to the person skilled in the art and which he considers to be suitable in the context of this invention can be employed as the solvent in the thermosetting system. According to the invention preferred solvents are those which allow the preferred high level of printability of the electro-conductive paste as described above to be achieved. Preferred solvents according to the invention are those which exist as a liquid under standard ambient temperature and pressure (SATP) (298.15 K, 25° C., 77° F.), 100 kPa (14.504 psi, 0.986 atm), preferably those with a boiling point above about 90° C. and a melting point above about −20° C.

Preferred solvents according to the invention are polar or non-polar, protic or aprotic, aromatic or non-aromatic, wherein protic polar solvents are preferred according to one aspect of this embodiment. Preferred solvents according to the invention are mono-alcohols, dialcohols, poly-alcohols, mono-esters, di-esters, poly-esters, mono-ethers, di-ethers, poly-ethers, solvents which comprise at least one or more of these categories of functional group, optionally comprising other categories of functional group, preferably cyclic groups, aromatic groups, unsaturated-bonds, alcohol groups with one or more O atoms replaced by heteroatoms, ether groups with one or more O atoms replaced by heteroatoms, esters groups with one or more O atoms replaced by heteroatoms, and mixtures of two or more of the aforementioned solvents. Preferred esters in this context are di-alkyl esters of adipic acid, preferred alkyl constituents being methyl, ethyl, propyl, butyl, pentyl, hexyl and higher alkyl groups or combinations of two different such alkyl groups, preferably dimethyladipate, and mixtures of two or more adipate esters. Preferred ethers in this context are diethers, preferably dialkyl ethers of ethylene glycol, preferred alkyl constituents being methyl, ethyl, propyl, butyl, pentyl, hexyl and higher alkyl groups or combinations of two different such alkyl groups, and mixtures of two diethers. Preferred alcohols in this context are primary, secondary and tertiary alcohols, preferably tertiary alcohols, terpineol and its derivatives being preferred, or a mixture of two or more alcohols. Preferred solvents which combine more than one different functional groups are 2,2,4-trimethyl-1,3-pentanediol monoisobutyrate, often called texanol, and its derivatives, 2-(2-ethoxyethoxy)ethanol, often known as carbitol, its alkyl derivatives, preferably methyl, ethyl, propyl, butyl, pentyl, and hexyl carbitol, preferably hexyl carbitol or butyl carbitol, and acetate derivatives thereof, preferably butyl carbitol acetate, or mixtures of at least 2 of the aforementioned.

### Thermoplastic System

In at least one embodiment of the invention, the polymer system is a thermoplastic system. Preferred thermoplastic systems in the context of the invention ensure that the constituents of the electro-conductive paste are present in the form of solutions, emulsions or dispersions and facilitate the formation of a solid electrode on heating. Preferred thermoplastic systems are those which provide optimal stability of constituents within the electro-conductive paste and endow the electro-conductive paste with a viscosity allowing effective line printability.

Preferred thermoplastic systems according to the invention comprise as components:

1. A thermoplastic polymer;

2. A solvent.

In at least one embodiment of the invention, it is preferred that the thermoplastic system not exhibit any thermal hysteresis of hardness when heating and cooling to any temperature below the melting temperature of the thermoplastic polymer.

### Thermoplastic Polymer

Thermoplastic polymers are well known to the skilled person and he may employ any thermoplastic polymer which he considers suitable for enhancing the favourable properties of the paste or resultant electrode, in particular the curing capability of the paste and the electrical contact between the electrode and the substrate. Preferred thermoplastic polymers show good adhesion on the wafer of the photovoltaic solar cell, are chemically stable under the conditions under which the photovoltaic solar cell is operated in order to guaranty a long operation time of the photovoltaic solar cell, shall not melt at the operation temperatures of the photovoltaic solar cell and should not particular harm the conductivity of the Ag electrode of the photovoltaic solar cell.

Preferred thermoplastic polymers are linear homo- and copolymers. Preferred thermoplastic polymers in the context of the invention are one or more selected from the following list: PVB (polyvinylbutyral); PE (polyethylene); PP (polypropylene), PS (polystyrene); ABS (copolymer of acrylonitrile, butadiene and styrene); PA (polyamide); PC (polycarbonate); polyester, preferably Vitel 2700B from Bostik, Inc.; poly acrylate, preferably Paraloid B44 from Dow Chemical; phenoxy polymer, preferably PKHH from InChem Corp.

### Solvent in the Thermoplastic System

The solvents in the thermoplastic system are preferably constituents of the thermoplastic system which are removed to a significant extent during heating, preferably those which are present after heating with an absolute weight reduced by at least about 80% compared to before heating, preferably reduced by at least about 95% compared to before heating.

Preferred solvents according to the invention are those which allow an electroconductive paste to be formed which has favourable viscosity, printability, stability and adhesive characteristics and which yields electrodes with favourable electrical conductivity and electrical contact to the substrate. Solvents are well known to the person skilled in the art. All solvents which are known to the person skilled in the art and which he considers to be suitable in the context of this invention can be employed as the solvent in the organic vehicle. According to the invention preferred solvents are those which allow the preferred high level of printability of the electro-conductive paste as described above to be achieved. Preferred solvents according to the invention are those which exist as a liquid under standard ambient temperature and pressure (SATP) (298.15 K, 25° C., 77° F.), 100 kPa (14.504 psi, 0.986 atm), preferably those with a boiling point above about 90° C. and a melting point above about −20° C.

Preferred solvents for the thermoplastic system are poor hydrogen bonding solvents or moderate hydrogen bonding solvents.

Preferred poor hydrogen bonding solvents are aromatics, aliphatics or halogenated solvents. Preferred poor hydrogen bonding solvents are those with a Hildebrand parameter in the range from about 8.5 to about 12, preferably benzene (Hildebrand parameter 9.2), monochlorobenzene (Hildebrand parameter 9.5), or 2-Nitropropane (Hildebrand parameter 10.7).

Preferred moderate hydrogen bonding solvents are solvents comprising esters, ethers or ketones. Preferred moderate hydrogen bonding solvents are those with a Hildebrand parameter in the range from about 8.3 to about 10.5, preferably THF (Tetrahydrofuran—Hildebrand parameter 9.8), cyclohexanone (Hildebrand parameter 9.9), or n-butyl acetate (Hildebrand parameter 8.0).

The following are also preferred solvents for the thermoplastic system: DMPU (1,3-dimethyl-3,4,5,6-tetrahydro-2(1H)-pyrimidinone), iso-tridecanol, dichloromethane, HMPT (hexamethylphosphoramide), DMSO (dimethyl sulfoxide), dioxane, methyl cellusolve (2-methoxyethanol), cellosolve acetate (ethylene glycol monoethyl ether acetate), MEK (methyl ethyl ketone), acetone, nitroethane, xylene, toluene, solvent naphtha (petroleum) heavy aromatic, NMP (N-Methyl-2-pyrrolidone), glycol ethers, glycol esters.

### Additives in the Electro-Conductive Paste

Preferred additives in the context of the invention are constituents added to the electro-conductive paste, in addition to the other constituents explicitly mentioned, which contribute to increased performance of the electro-conductive paste, of the electrodes produced thereof or of the resulting solar cell. All additives known to the person skilled in the art and which he considers suitable in the context of the invention can be employed as additive in the electro-conductive paste. In addition to additives present in the vehicle, additives can also be present in the electro-conductive paste. Preferred additives according to the invention are thixotropic agents, viscosity regulators, emulsifiers, stabilising agents or pH regulators, thickeners and dispersants or a combination of at least two thereof.

### Microwave Sintering Agents as Additives

In at least one embodiment of the invention sintering agents with particular microwave activity as SiC could be used. The purpose of this is to allow better coupling of the wave into the paste. This particular can help to protect the wafer from overheating and damaging the amorphous layers by the MW.

### Radical Generator

In at least one embodiment of the invention, a radical generator is further comprised in the paste. Radical generators are well known to the skilled person and he can select a radical generator which is suitable for bringing about advantageous properties, such as hardening and/or adhesion. Quite often, hardening and adhesion is accomplished by cross-linking reactions, preferably based on at least two double bonds per molecule to be cross-linked, preferably triggered by generators. Preferred radical generators in the context of the invention are those which initiate a radical chain reaction in the above described polymers, preferably a cross-linking chain reaction. Preferred radical generators are peroxides, preferably organic peroxides; and azo compounds, preferably organic azo compounds.

In a further embodiment of the invention, the thermosetting system does not require a radical generator. Alternative means of initiating the thermosetting process include heating or exposure to light or other electro-magnetic radiation, e.g. electron beam radiation or UV irradiation.

### Preparation of a Solar Cell Precursor

A contribution to achieving at least one of the above described objects is made by a HIT solar cell precursor. Preferred methods for preparation of HIT solar cell precursors according to the invention comprise the following steps:
a) providing a substrate wherein the substrate comprises amorphous layers on each surface of the substrate respectively,
b) providing an electroconductive paste comprising as constituents metallic particles and a polymer system,
c) applying the electroconductive paste to the substrate surface to obtain a precursor.

In the obtained precursor, preferably the electroconductive paste is located on or over at least one surface of the wafer. The paste may be in physical contact with the silicon wafer or alternatively it may be in contact with the outermost of one or more further layers which are present in between the silicon wafer and the paste, such as a transparent conductive layer or a physically protective layer.

In at least one embodiment of the invention, one or more further pastes are present on the substrate in addition to the paste according to the invention.

HIT type solar cell precursors are preferred in the context of the invention. In one aspect of this embodiment, the wafer comprises at least one layer of amorphous Si. Preferably, at least one layer of amorphous Si is n-type doped. Preferably, at least one layer of amorphous Si is p-type doped. Preferably at least one or more than one, preferably two, layers of amorphous Si are intrinsic (non-doped). Preferably, the wafer comprises at least one crystalline layer, preferably n-type doped or p-type doped.

In the preparation of the solar cell precursor, it is preferred for the temperature to be maintained low, preferably below 100° C., more preferably below about 80° C., most preferably below about 60° C.

### Printing

It is preferred according to the invention that the precursor is prepared by applying an electro-conductive paste to the substrate and then heating the precursor by using microwave radiation to obtain a solar cell. The electro-conductive paste can be applied to the substrate in any manner known to the person skilled in that art and which he considers suitable in the context of the invention including but not limited to impregnation, dipping, pouring, dripping on, injection, spraying, knife coating, curtain coating, brushing or printing or a combination of at least two thereof, wherein preferred printing techniques are ink-jet printing, screen printing, tampon printing, offset printing, relief printing or stencil printing or a combination of at least two thereof. It is preferred according to the invention that the electro-conductive paste is applied by printing, preferably by screen printing. It is preferred according to the invention that the screens have mesh opening with a diameter in a range from about 20 to about 100 μm, more preferably in a range from about 30 to about 80 μm, and most preferably in a range from about 40 to about 70 μm. As detailed in the solar cell precursor section, it is preferred for the electroconductive paste applied to the channel to be as described in this invention. The electro-conductive pastes used to form the front and back electrodes can be the same or different to the paste used in the channel, preferably different, and can be the same as or different to each other.

It is preferred for printing not to be carried out at a high temperature, preferably below 100° C., more preferably below about 80° C., more preferably below about 50° C. in order to avoid unwanted curing.

### Method for Producing a HIT Solar Cell

A contribution to achieving at least one of the aforementioned objects is made by a process for producing a HIT solar cell at least comprising the following as process steps:
i) obtaining a solar cell precursor according to the invention;
ii) heating of the solar cell precursor through microwave radiation to obtain a solar cell.

By heating of the solar cell precursor through microwave radiation, a functional solar cell electrode can be produced. This electrode is an integral part of the obtained HIT solar cell.

It is preferred according to the invention for electrodes to be formed by first applying an electro-conductive paste and then heating said electro-conductive paste by using microwave radiation to yield a solar cell.

Heating of electro-conductive pastes on the front face and back face can be carried out simultaneously or sequentially. Simultaneous heating is appropriate if the electro-conductive pastes have similar, preferably identical, optimum heating conditions. Where appropriate, it is preferred according to the invention for heating to be carried out simultaneously.

### Microwave Heating

According to the invention, the heating of the precursor is done through microwave radiation which provides a certain power density at the substrate surface (surface power density).

It is preferred that the heating step of the precursor is carried out for a time of 60 sec or less, preferably for a time of 20 sec or less. This is much shorter than the typical curing time in a box oven of the state of the art.

In a preferred embodiment of the invention the microwave radiation is monomodal microwave radiation.

In the method according to the invention the microwave radiation preferably has a frequency from 2-3 GHz and even more preferred in the range from 2.3-2.7 GHz and most preferably the frequency is 2.5 GHz.

The source used for irradiating the precursor preferably operates at a power of at least 100 W, preferably at least 200 W and more preferably of at least 400 W and the same time the microwave source operates at a power of not more than 1000 W, preferably not more than 750 W and most preferably not more than 500 W.

In another preferred embodiment, the microwave surface power density applied to the precursor is in the range from 0.1 to 30 W/cm², preferably in the range from 0.5-2.5 W/cm². Preferably, the surface power density is the average power density over the whole irradiation time. The energy applied to the wafer by means of microwave radiation is preferably chosen such that the electroconductive paste on the precursor is cured but no recrystallization of the amorphous layers of the substrate, preferably a Si-wafer, is induced.

Preferably the microwave energy applied to the precursor is chosen such that the metallic particles of the electroconductive paste are partly or completely molten.

Surprisingly it was found that by using the method of the invention which uses microwave radiation for heating much lower grid resistance values of the electrode could be achieved-In addition it was found that the processing time can by reduced by a factor of 50-100.

### Solar Cell

A contribution to achieving at least one of the above mentioned objects is made by a HIT solar cell at least comprising as HIT solar cell parts:
i) a substrate;
ii) an electrode;
   wherein the material density of the electrode is at least 70%, preferably at least 90% relative to the bulk density of the total solid material present in the electrode.

A contribution to achieving at least one of the above described objects is made by a solar cell obtainable by a process according to the invention. Preferred solar cells according to the invention are those which have a high efficiency in terms of proportion of total energy of incident light converted into electrical energy output and which are light and durable.

### Transparent Conductive Layer

Preferred transparent conductive layers in the context of the invention are layers on or over the silicon wafer which have a high transparency and conductivity. The transmission of light with a wavelength of 400 nm through the layer is preferably above about 50%, more preferably above about 80%, most preferably above about 90%. The electrical conductivity of the layer is preferably above about 1*10⁻⁴Ω⁻¹ cm⁻¹, more preferably above about 5*10⁻³Ω⁻¹ cm⁻¹, most preferably above about 5*10⁻²Ω⁻¹ cm⁻¹.

The thickness of the transparent conductive layer is preferably in the range from about 30 to about 500 nm, more preferably in the range from about 50 to about 400 nm, most preferably in the range from about 80 to about 300 nm.

Transparent conductive materials are well known to the skilled person and he may select the material in order to improve the advantageous properties of the solar cell, such as conductivity, transparency and adhesion. Preferred materials are oxides, conductive polymers or carbon nanotube based conductors, preferably oxides. Preferred oxides are indium tin oxide (ITO), fluorine doped tin oxide (FTO) or doped zinc oxide, preferably indium tin oxide. Preferred conductive polymers are organic compounds with conjugated double bonds, preferably polyacetylenes, polyanilines, polypyrroles or polythiophenes or derivatives thereof, or combinations thereof.

In at least one embodiment, the solar cell has a transparent conductive layer on the front face.

### Electrodes

Surprisingly it could be found that the material density of the electrodes which have been produced according to the method of the invention is at least 70% relative to the bulk density of the total solid material present in the electrode. Preferably, the material density of the electrodes is at least 90% relative to the bulk density of the total solid material present in the electrode. The total solid material is the sum of all solid components in the electrode. The solid material contains at least conductive metal and a polymer system and it can optionally contain additional components like e.g. glass or additives. The bulk density of the solid material is a mixed density of the aforementioned solid materials. The material density of the electrode is determined by SEM according to the method described below.

### Additional Protective Layers

In addition to the layers described above which directly contribute to the principle function of the solar cell, further layers can be added for mechanical and chemical protection. The cell can be encapsulated to provide chemical protection. Encapsulations are well known to the person skilled in the art and any encapsulation can be employed which is known to him and which he considers suitable in the context of the invention. According to the invention, transparent polymers, often referred to as transparent thermoplastic resins, are preferred as the encapsulation material, if such an encapsulation is present. Preferred transparent polymers in this context are for example silicon rubber and polyethylene vinyl acetate (PVA).

A transparent glass sheet can be added to the front of the solar cell to provide mechanical protection to the front face of the cell. Transparent glass sheets are well known to the person skilled in the art and any transparent glass sheet known to him and which he considers to be suitable in the context of the invention can be employed as protection on the front face of the solar cell.

A back protecting material can be added to the back face of the solar cell to provide mechanical protection. Back protecting materials are well known to the person skilled in the art and any back protecting material which is known to the person skilled in the art and which he considers to be suitable in the context of the invention can be employed as protection on the back face of the solar cell. Preferred back protecting materials according to the invention are those having good mechanical properties and weather resistance. The preferred back protection materials according to the invention is polyethylene terephthalate with a layer of polyvinyl fluoride. It is preferred according to the invention for the back protecting material to be present underneath the encapsulation layer (in the event that both a back protection layer and encapsulation are present).

A frame material can be added to the outside of the solar cell to give mechanical support. Frame materials are well known to the person skilled in the art and any frame material known to the person skilled in the art and which he considers suitable in the context of the invention can be employed as frame material. The preferred frame material according to the invention is aluminium.

FIG. 1 shows a cross sectional view of a common HIT type layer configuration for a solar cell. Preferably this layer configuration is also present in the solar cell according to the invention. 101 are electrodes, preferably in the form of fingers, preferably obtained by a method according to the invention. 201 and 105 is one or more optional layers, preferably comprising a transparent conductive layer, such as indium tin oxide. 202 is an amorphous front layer, preferably an Si layer, of a first doping type, n-type or p-type, preferably p-type. 203 is an intrinsic (non-doped) amorphous front layer, preferably an Si layer. 204 is crystalline layer, preferably an Si layer, preferably n-type doped. 205 is an intrinsic (non-doped) amorphous back layer. 206 is an amorphous front layer, preferably an Si layer, or the opposite doping type to the first doping type, preferably n-type doped.

### Test Methods

The following test methods are used in the invention. In absence of a test method, the ISO test method for the feature to be measured being closest to the earliest filing date of the present application applies. In absence of distinct measuring conditions, standard ambient temperature and pressure (SATP) as a temperature of 298.15 K (25° C., 77° F.) and an absolute pressure of 100 kPa (14.504 psi, 0.986 atm) apply.

### Specific Surface Area

BET measurements to determine the specific surface area of silver particles are made in accordance with DIN ISO 9277:1995. A Gemini 2360 (from Micromeritics) which works according to the SMART method (Sorption Method with Adaptive dosing Rate), is used for the measurement. As reference material Alpha aluminum oxide CRM BAM-PM-102 available from BAM (Bundesanstalt für Materialforschung und -prüfung) is used. Filler rods are added to the reference and sample cuvettes in order to reduce the dead volume. The cuvettes are mounted on the BET apparatus. The saturation vapour pressure of nitrogen gas (N₂ 5.0) is determined. A sample is weighed into a glass cuvette in such an amount that the cuvette with the filler rods is completely filled and a minimum of dead volume is created. The sample is kept at 80° C. for 2 hours in order to dry it. After cooling the weight of the sample is recorded. The glass cuvette containing the sample is mounted on the measuring apparatus. To degas the sample, it is evacuated at a pumping speed selected so that no material is sucked into the pump. The mass of the sample after degassing is used for the calculation. The dead volume is determined using Helium gas (He 4.6). The glass cuvettes are cooled to 77 K using a liquid nitrogen bath. For the adsorptive, N₂ 5.0 with a molecular cross-sectional area of 0.162 nm² at 77 K is used for the calculation. A multi-point analysis with 5 measuring points is performed and the resulting specific surface area given in m²/g.

### Viscosity

Viscosity measurements were performed using the Thermo Fischer Scientific Corp. “Haake Rheostress 600” equipped with a ground plate MPC60 Ti and a cone plate C 20/0.5° Ti and software “Haake RheoWin Job Manager 4.30.0”. After setting the distance zero point, a paste sample sufficient for the measurement was placed on the ground plate. The cone was moved into the measurement positions with a gap distance of 0.026 mm and excess material was removed using a spatula. The sample was equilibrated to 25° C. for three minutes and the rotational measurement started. The shear rate was increased from 0 to 20 s⁻¹ within 48 s and 50 equidistant measuring points and further increased to 150 s⁻¹ within 312 s and 156 equidistant measuring points. After a waiting time of 60 s at a shear rate of 150 s⁻¹, the shear rate was reduced from 150 s⁻¹ to 20 s⁻¹ within 312 s and 156 equidistant measuring points and further reduced to 0 within 48 s and 50 equidistant measuring points. The micro torque correction, micro stress control and mass inertia correction were activated. The viscosity is given as the measured value at a shear rate of 100 s-1 of the downward shear ramp.

Particle Size Determination (d₁₀, d₅₀, d₉₀ and Particle Distribution of Powder)

Particle size determination for particles is performed in accordance with ISO 13317-3:2001. A Sedigraph 5100 with software Win 5100 V2.03.01 (from Micromeritics) which works according to X-ray gravitational technique is used for the measurement. A sample of about 400 to 600 mg is weighed into a 50 ml glass beaker and 40 ml of Sedisperse P11 (from Micromeritics, with a density of about 0.74 to 0.76 g/cm³ and a viscosity of about 1.25 to 1.9 mPa·s) are added as suspending liquid. A magnetic stirring bar is added to the suspension. The sample is dispersed using an ultrasonic probe Sonifer 250 (from Branson) operated at power level 2 for 8 minutes while the suspension is stirred with the stirring bar at the same time. This pre-treated sample is placed in the instrument and the measurement started. The temperature of the suspension is recorded (typical range 24° C. to 45° C.) and for calculation data of measured viscosity for the dispersing solution at this temperature are used. Using density and weight of the sample (10.5 g/cm³ for silver) the particle size distribution function is determined. d₅₀, d₁₀ and d₉₀ can be read directly from the particle distribution function. For the evaluation of multimodal size, distribution plots of mass frequency against diameter are generated and the peak maxima are determined therefrom.

### Scanning Electron Microscopy (SEM) and Energy Dispersive X-Ray Spectroscopy (EDX)

The solar cell is cut in a way that the area of interest is laid open. The cut sample is placed in a container filled with embedding material and oriented such that the area of interest is on top. As embedding material, EpoFix (Struers) is used, mixed according to the instructions. After 8 hours curing at room temperature the sample can be processed further. In a first step the sample is ground with a Labopol-25 (Struers) using silicon carbide paper 180-800 (Struers) at 250 rpm. In further steps the sample is polished using a Rotopol-2 equipped with a Retroforce4, MD Plano 220 and MD allegro cloth and DP-Spray P 3 μm diamond spray (all from Struers). Coating with a carbon layer is performed with a Med 010 (Balzers) at a pressure of 2 mbar using a carbon thread 0.27 g/m E419ECO (from Plano GmbH). The examination was performed with a Zeiss Ultra 55 (Zeiss), equipped with a field emission electrode, an accelerating voltage of 20 kV and at a pressure of about 3*10⁻⁶ mbar. Images of relevant areas were taken and analysed using image analysis software ImageJ Version 1.46r (Image Processing and analysis in Java, by Wayne Rasband, http://rsb.info.nih.gov/ij). In order to identify Ag particles, the intense Ag_{L} signal at about 3.4 keV in EDX was used to identify 10 silver particles and the average SEM greyscale intensity for those 10 particles was used to identify further Ag particles from the SEM picture.

### Grid Resistivity

The line resistivity of 1 cm of the finger was measured by using a “GP4-Test. Pro” equipped with software package “GP-4 Test 1.6.6 Pro” from the company GP solar. For the measuring the 4 point measuring principle is applied. Therefore the two outer probes apply a constant current (10 mA) and two inner probes measure the voltage. The line resistivity is deducted by the Ohmic law in Ohm/cm. The cross section of the measured 1 cm of the finger line was determined by using a “Cyberscan Vantage” (model 2V4-C/5NVK) equipped with the software package “Scan CT 7.6” from the company cyberTechnologies GmbH. The specific line resistivity was calculated by using the determined values for the line resistivity and the cross section of the same 1 cm of the cured finger line in Ω.

Specific Contact Resistance

In an air conditioned room with a temperature of 22±1° C., all equipment and materials are equilibrated before the measurement. For measuring the specific contact resistance of cured silver electrodes on the front side (texturized and coated with ITO) of a HIT solar cell a “GP4-Test Pro” equipped with the “GP-4 Test 1.6.6 Pro” software package from the company GP solar GmbH is used. This device applies the 4 point measuring principle and estimates the specific contact resistance by the transfer length method (TLM). To measure the specific contact resistance, two 1 cm wide stripes of the wafer are cut perpendicular to the printed finger lines of the wafer. The exact width of each stripe is measured by a micrometer with a precision of 0.05 mm. The width of the fired silver fingers is measured on 3 different spots on the stripe with a digital microscope “VHX—600D” equipped with a wide-range zoom lens VH-Z100R from the company Keyence Corp. On each spot, the width is determined ten times by a 2-point measurement. The finger width value is the average of all 30 measurements. The finger width, the stripe width and the distance of the printed fingers to each other is used by the software package to calculate the specific contact resistance. The measuring current is set to 14 mA. A multi contact measuring head (part no. 04.01.0016) suitable to contact six neighboring finger lines is installed and brought into contact with 6 neighboring fingers. The measurement is performed on 5 spots equally distributed on each stripe. After starting the measurement, the software determines the value of the specific contact resistance (mOhm*cm²) for each spot on the stripes. The average of all ten spots is taken as the value for specific contact resistance.

### Analysis of Material Density of the Electrode

The material density of the electrode is measured by SEM. For this purpose a final solar cell is broken into halves perpendicular to the direction of the electrode lines. The cross-sectional image of an electrode is measured according to parameters which are well know the skilled person in the field of SEM. In the cross-sectional image the area covered by solid electrode material (mainly silver and some polymer) is determined by image analysis. It is assumed that the volume between particles or in the voids is occupied by gas, e.g. air. The area attributed to the solid material is divided by total area of the electrode in the cross-sectional image and the resulting value is multiplied by a factor of 100.

The area calculation at different spots of the electrode can be done automatically by imaging software using a grey scale contrast to obtain density measurement at different spots. The mean value of the material density of the electrode is calculated from several different spots of the SEM cross sectional image.

### EXAMPLES

The invention is now explained by means of examples which are intended for illustration only and are not to be considered as limiting the scope of the invention.

### Example 1—Paste Preparation—Thermoplastic

By means of a Kenwood Major Titanium mixer a paste was made by homogenizing the appropriate amounts organic vehicle (Table 1) comprising a thermoplastic polymer (1. polyester: Vitel 2700B from Bostik, Inc.) and Butyl carbitol acetate from Sigma Aldrich as an organic solvent and silver particles (a flake Ag powder (AC-4048 from Metalor Technologies, with a peak maxima according to the above test method of 1.8 μm) or a smaller spherical Ag powder (TZ-A04 from Dowa Electronics Materials CO., LTD., with a peak maxima according to the above test method of 0.3 μm) or a bigger spherical Ag powder (Silver Powder 11000-06 from Ferro Electronic Material Systems, with a peak maxima according to the above test method of 1.5 μm) or mixtures thereof).

The paste was passed through a 3-roll mill Exact 80 E with stainless steel rolls with a first gap of 120 μm and a second gap of 60 μm with progressively decreasing gaps to 20 μm for the first gap and 10 μm for the second gap several times until homogeneity.

TABLE 1
Constitution of thermoplastic polymer system.

| Example | | |
|---|---|---|
| [wt. %] | Polyester | Butyl carbitol acetate |
| 1 (inventive) | 26 | 74 |

TABLE 2
Paste Example

| Example | | Thermoplastic | Butyl carbitol |
|---|---|---|---|
| [wt. %] | Silver powder | polymer system | acetate |
| 1 (inventive) | 87 | 10 | 3 |

### Solar Cell Preparation and Measurement of Cell Properties

Pastes were applied to mono-crystalline HIT solar cell wafers from Meyer Burger Technology AG, Switzerland. The wafers had dimensions of 156×156 mm². The solar cells used were textured by alkaline etching and had an ITO (indium-tin-oxide) layer on the surface. The example paste was screen-printed onto the texturized ITO-layer using a semi-automatic screen printer X1 SL from Asys Group, EKRA Automatisierungssysteme set with the following screen parameters: 360 mesh, 20 μm wire thickness, 18 μm emulsion over mesh, 101 fingers, 45 μm finger opening, 4 bus bars, 1.2 mm bus bar width. The device with the printed patterns was cured for under different conditions according to Table 4.

The microwave used had the following technical specifications:

TABLE 3
microwave data

| | |
|---|---|
| Max Output Power | 1000 W (IEC-705) |
| Operating Frequency | 2450 MHz |
| Surface power density | 1-1.5 W/cm² |

TABLE 4
Curing conditions and grid resistance GRFr3 and contact resistance
Rc after sintering for two different paste batches (A and B)

| | | | GRFr3 | |
|---|---|---|---|---|
| Curing/Sintering Equipment | Example | Time | (Ω) | Rc (Ω) |
| Box Oven (comparison) | A | 10 Minutes | 371 | 0.915 |
| Microwave | A | 10 Seconds | 191 | 0.6375 |
| Microwave | A | 20 Seconds | 150 | 0.6175 |
| Box Oven (comparison) | B | 10 Minutes | 362 | 0.8045 |
| Microwave | B | 10 Seconds | 214 | 0.592 |
| Microwave | B | 20 Seconds | 163 | 0.5285 |

As can be seen from the results of the electrical measurements heating the precursor by using microwave radiation significantly reduces the grid and contact resistance compared to the conventional box oven heating.

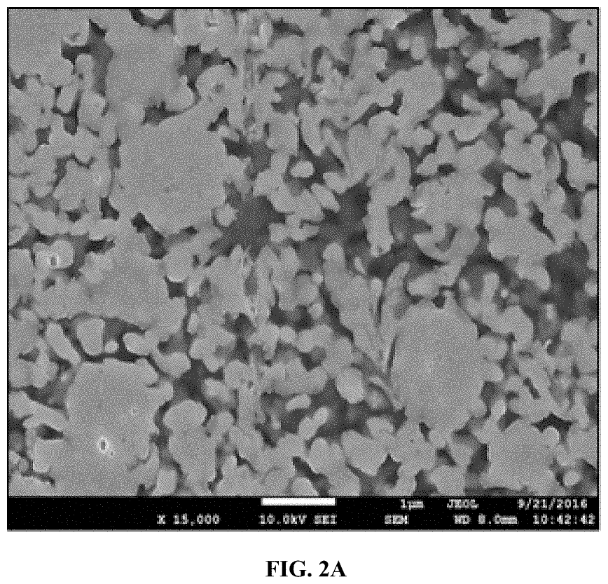

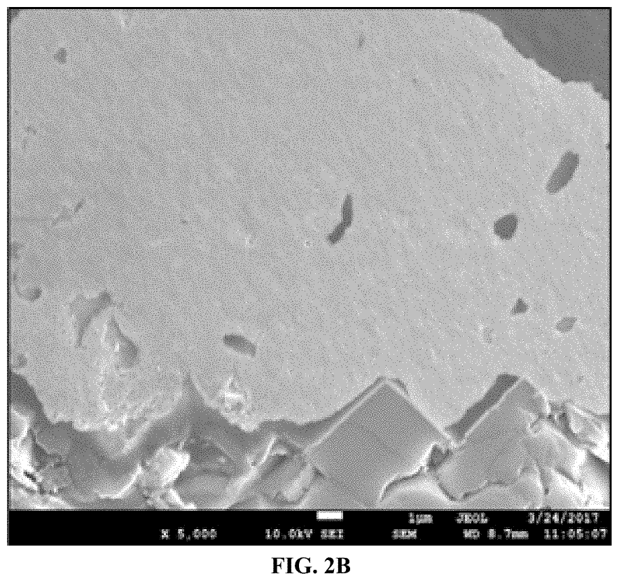

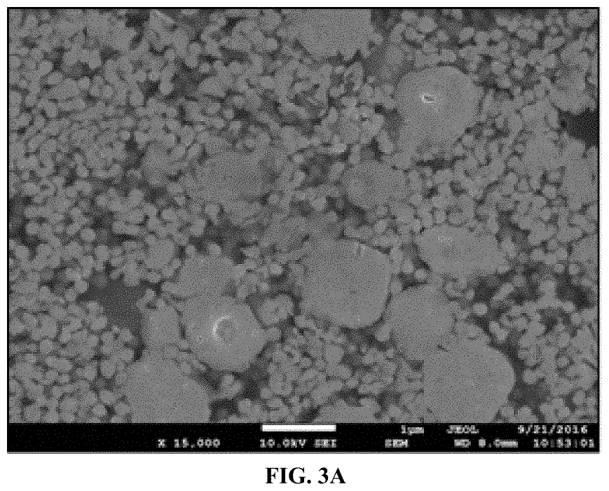

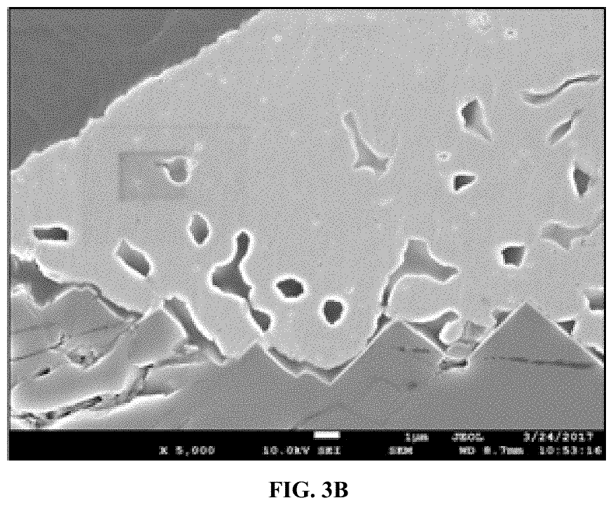

FIG. 2A and FIG. 3A show SEM cross-sectional images of an electrode prepared by conventional box oven heating. As can be seen from the images the metallic particles basically retain their morphology and are randomly contacting each other. Between the particles big cavities can be seen. The cavities may contain enclosed gas bubbles or parts from the organic vehicle.

FIG. 2B and FIG. 3B show SEM cross-sectional images of an electrode prepared by microwave heating. As can be seen from the images the metallic particles are not visible anymore but the metallic parts are predominantly molten to form continuous metallic regions with little or no porosity.

### REFERENCE LIST

101 Front electrodes
105 TCO, indium tin oxide
201 TCO, indium tin oxide
202 Front doped amorphous layer
203 Front intrinsic amorphous layer
204 Crystalline layer
205 Back intrinsic amorphous layer
206 Back doped amorphous layer

### STATEMENTS OF THE DISCLOSURE

Statements of the Disclosure include:

Statement 1: A method for making a HIT solar cell comprising the steps of a) providing a substrate wherein the substrate comprises amorphous layers on the surfaces of the substrate respectively, b) providing an electroconductive paste comprising as constituents metallic particles and a polymer system, c) applying the electroconductive paste to the substrate surface to obtain a precursor, and d) heating the precursor through microwave radiation to obtain a solar cell.

Statement 2: A method according to Statement 1, wherein the heating step c) is carried out for a time of 60 seconds or less.

Statement 3: A method according to Statement 1 of 2, wherein the heating step c) is carried out for a time of 20 seconds or less.

Statement 4: A method according to any one of Statements 1-3, wherein the microwave radiation is monomodal and has a frequency in the range from 2 to 3 GHz.

Statement 5: A method according to any one of Statements 1-4, wherein the microwave radiation provides a microwave surface power density in the range from 0.1 to 30 W/cm².

Statement 6: A method according to any one of Statements 1-5, wherein the microwave radiation provides a microwave surface power density in the range from 0.5 to 2.5 W/cm².

Statement 7: A method according to any one of Statements 1-6, wherein the electroconductive paste comprises at least one glass frit.

Statement 8: A method according to any one of Statements 1-7, wherein the metallic particles are silver particles.

Statement 9: A method according to any one of Statements 1-8, wherein the polymer system comprises a thermoplastic polymer.

Statement 10: An HIT solar cell prepared according to a method according to any one of Statements 1-9, wherein the density of the electrodes is at least 70% relative to the bulk density of the solid material present in the electrode.

Statement 11: An HIT solar cell according to Statement 10, wherein the material density of the electrodes is at least 90% relative to the bulk density of the solid material present in the electrode.

Statement 12: An HIT solar cell according to Statement 10 or 11, wherein the electrode of the HIT solar cell is substantially glass free.

Although the present invention and its objects, features and advantages have been described in detail, other embodiments are encompassed by the invention. All references cited herein are incorporate by reference in their entireties. Finally, those skilled in the art should appreciate that they can readily use the disclosed conception and specific embodiments as a basis for designing or modifying other structures for carrying out the same purposes of the present invention without departing from the scope of the invention as defined by the appended claims.

1. A method for making a HIT solar cell comprising the steps of:
d) providing a substrate wherein the substrate comprises amorphous layers on the surfaces of the substrate respectively,
e) providing an electroconductive paste comprising as constituents metallic particles and a polymer system,
f) applying the electroconductive paste to the substrate surface to obtain a precursor, and
g) heating the precursor through microwave radiation to obtain a solar cell.

2. The method of claim 1, wherein the heating step c) is carried out for a time of 60 seconds or less.

3. The method of claim 1, wherein the heating step c) is carried out for a time of 20 seconds or less.

4. The method of claim 1, wherein the microwave radiation is monomodal and has a frequency in the range from 2 to 3 GHz.

5. The method of claim 1, wherein the microwave radiation has a microwave power density at the substrate surface in the range from 0.1 to 30 W/cm².

6. The method of claim 1, wherein the microwave radiation has a microwave power density at the substrate surface in the range from 0.5 to 2.5 W/cm².

7. The method according of claim 1, wherein the electroconductive paste comprises at least one glass frit.

8. The method of claim 1, wherein the metallic particles are silver particles.

9. The method of claim 1, wherein the polymer system comprises a thermoplastic polymer.

10. An HIT solar cell prepared according to the method of claim 1, wherein the density of the electrodes is at least 70% relative to the bulk density of the solid material present in the electrode.

11. The HIT solar cell of claim 10, wherein the material density of the electrodes is at least 90% relative to the bulk density of the solid material present in the electrode.

12. The HIT solar cell of claim 11, wherein the electrode of the HIT solar cell is substantially glass free.

13. The HIT solar cell of claim 10, wherein the electrode of the HIT solar cell is substantially glass free.
